(19) United States
(12) Patent Application Publication
(10) Pub. No.: US 2019/0376206 A1
(43) Pub. Date: Dec. 12, 2019

(54) SiC EPITAXIAL WAFER AND METHOD FOR PRODUCING SAME

(71) Applicants: SHOWA DENKO K.K., Tokyo (JP); Central Research Institute of Electric Power Industry, Tokyo (JP); DENSO CORPORATION, Kariya-shi, Aichi (JP)

(72) Inventors: Keisuke FUKADA, Chichibu-shi (JP); Naoto ISHIBASHI, Chichibu-shi (JP); Akira BANDO, Chichibu-shi (JP); Masahiko ITO, Yokosuka-shi (JP); Isaho KAMATA, Yokosuka-shi (JP); Hidekazu TSUCHIDA, Yokosuka-shi (JP); Kazukuni HARA, Kariya-shi (JP); Masami NAITO, Kariya-shi (JP); Hideyuki UEHIGASHI, Kariya-shi (JP); Hiroaki FUJIBAYASHI, Kariya-shi (JP); Hirofumi AOKI, Toyota-shi (JP); Toshikazu SUGIURA, Okazaki-shi (JP); Katsumi SUZUKI, Toyota-shi (JP)

(73) Assignees: SHOWA DENKO K.K, Tokyo (JP); Central Research Institute of Electric Power Industry, Tokyo (JP); DENSO CORPORATION, Kariya-shi, Aichi (JP)

(21) Appl. No.: 16/476,412

(22) PCT Filed: Dec. 25, 2017
(86) PCT No.: PCT/JP2017/046359

§ 371 Date: Jul. 8, 2019

(30) Foreign Application Priority Data
Jan. 10, 2017 (JP) 2017-001982

(51) Int. Cl. C30B 25/20; C30B 25/16; C30B 25/18; C30B 29/36; C30B 29/06; H01L 21/02

(52) U.S. Cl. CPC C30B 25/205; C30B 25/165; C30B 25/183; H01L 21/02271; C30B 29/06; H01L 21/02167; C30B 29/36

(57) ABSTRACT

This SiC epitaxial wafer includes: a SiC single crystal substrate of which a main surface has an off-angle of 0.4° to 5° with respect to (0001) plane; and an epitaxial layer provided on the SiC single crystal substrate, wherein the epitaxial layer has a basal plane dislocation density of 0.1 pieces/cm² or less that is a density of basal plane dislocations extending from the SiC single crystal substrate to an outer surface and an intrinsic 3C triangular defect density of 0.1 pieces/cm² or less.

### TECHNICAL FIELD

The present invention relates to a SiC epitaxial wafer and a method for producing a SiC epitaxial wafer. The present application claims priority on Japanese Patent Application No. 2017-001982 filed on Jan. 10, 2017, the content of which is incorporated herein by reference.

### BACKGROUND ART

Silicon carbide (SiC) has characteristics such that the dielectric breakdown field is larger by one order of magnitude (ten times larger), the band gap is three times larger, and the thermal conductivity is approximately three times higher than those of silicon (Si). Therefore, application of silicon carbide (SiC) to power devices, high-frequency devices, high-temperature operation devices, and the like is expected.

In order to promote the practical application of SiC devices, it is essential to establish high-quality epitaxial growth techniques and achieve high-quality SiC epitaxial wafers.

A SiC device is generally manufactured using a SiC epitaxial wafer. The SiC epitaxial wafer can be obtained by forming (growing) an epitaxial layer (film), which becomes an active region of the device, on a SiC single crystal substrate by using a chemical vapor deposition (CVD) method. The SiC single crystal substrate can be obtained by processing a bulk single crystal of SiC grown by a sublimation method or the like.

More specifically, in general, step-flow growth (lateral growth from an atomic step) is carried out on the SiC single crystal substrate using a plane having an off-angle in <11-20> direction from (0001) plane as a growth surface; and thereby, 4H of an epitaxial layer is grown.

In the SiC epitaxial wafer, a basal plane dislocation (BPD) is known as one of device killer defects that cause fatal defects in a SiC device.

Most of the basal plane dislocations in the SiC single crystal substrate may be converted into threading edge dislocations (TED) during formation of the epitaxial layer. On the other hand, a part of basal plane dislocations transferred into the epitaxial layer with no change may result in a device killer defect.

Therefore, the studies of reducing a ratio of basal plane dislocations transferred from the SiC single crystal substrate into the epitaxial layer and reducing a device killer defect are being carried out.

For example, Patent Document 1 discloses that thermal stress is applied so as to change migration of atoms attached to a SiC single crystal substrate by controlling a temperature in a crystal growth process, and a basal plane dislocation density in a SiC epitaxial wafer of 3 inches is set to 10 pieces/cm² or less.

In addition, for example, Patent Document 2 discloses that a basal plane dislocation density in a SiC epitaxial wafer is set to 10 pieces/cm² or less by controlling parameters such as reactant concentration, pressure, temperature and gas flow of CVD in a crystal growth process.

Furthermore, for example, Non-Patent Document 1 discloses that by setting a growth rate of an epitaxial layer to 50 μm/h, it is possible to reduce a ratio of BPDs transferred from the SiC single crystal substrate into the epitaxial layer to 1%. According to the current level of technology, since an amount of the basal plane dislocations existing on a surface of a SiC single crystal substrate of 6 inches is about 100 to 5000 pieces/cm², reducing the ratio of BPDs to 1% means that 10 to 50 pieces/cm² of the basal plane dislocations are generated on the surface of the SiC epitaxial layer.

In addition, Non-Patent Document 2 discloses that a basal plane dislocation density in an epitaxial wafer can be reduced by increasing a C/Si ratio.

In addition, Non-Patent Document 3 discloses that there is trade-off relation between a basal plane dislocation density and an intrinsic 3C triangular defect.

In recent years, in order to increase the number of SiC devices obtained from one epitaxial wafer and to reduce the manufacturing cost, an attempt is being performed to increase the size of the SiC epitaxial wafer to 6 inches or more. Accordingly, there is a demand for a low basal plane dislocation density even in a large SiC epitaxial wafer having a size of 6 inches or more.

However, each of the SiC epitaxial wafers disclosed in the above-described Patent Documents has SiC epitaxial wafer size of 6 inches or less. In the case where an above-described condition is simply applied to a process of producing a SiC epitaxial wafer having a size of 6 inches, since a substrate area is large, film forming conditions vary in a plane of the SiC single crystal substrate. Therefore, it is difficult to obtain the same result as in the case where the size is 4 inches.

In addition, in the case where a growth rate is too high, there is a problem that crystal defects such as triangular defects increase. For example, paragraph 0043 of Patent Document 3 discloses a concern that in the case where the growth rate of the crystal is too high, crystal defects are more likely to occur.

### PRIOR ART DOCUMENTS

### Patent Documents

Patent Document 1: Japanese Unexamined Patent Application, First Publication No. 2011-219299
Patent Document 2: Published Japanese Translation No. 2015-521378 of the PCT International Publication
Patent Document 3: Japanese Unexamined Patent Application, First Publication No. 2013-239606

### Non-Patent Documents

Non-Patent Document 1: T. Hori, K. Danno and T. Kimoto. Journal of Crystal Growth, 306 (2007) 297-302.
Non-Patent Document 2: W. Chen and M. A. Capano. JOURNAL OF APPLIED PHYSICS 98, 114907 (2005).
Non-Patent Document 3: H. Tsuchida, M. Ito, I. Kamata and M. Nagano. Materials Science Forum Vol. 615-617 (2009) pp 67-72.

### DISCLOSURE OF THE INVENTION

### Problems to be Solved by the Invention

The present invention has been made in view of the above problems, and an object of the present invention is to obtain a SiC epitaxial wafer, and a method for producing a SiC epitaxial wafer with less generation of basal plane dislocations and intrinsic 3C triangular defects which result in device killer defects.

### Solutions for Solving the Problems

As a result of intensive studies, the present inventors found that a SiC epitaxial wafer with less generation of basal plane dislocations and intrinsic 3C triangular defects is obtained by providing a ramping step of gradually adjusting crystal growth conditions to high-rate epitaxial growth conditions and a high-rate growth step of epitaxially growing a crystal at a high rate.

Accordingly, the present invention provides the following solutions in order to solve the above problems.

(1) A SiC epitaxial wafer according to an aspect of the present invention includes: a SiC single crystal substrate of which a main surface has an off-angle of 0.4° to 5° with respect to (0001) plane; and an epitaxial layer provided on the SiC single crystal substrate, in which the epitaxial layer has a basal plane dislocation density of 0.1 pieces/cm² or less that is a density of basal plane dislocations extending from the SiC single crystal substrate to an outer surface and an intrinsic 3C triangular defect density of 0.1 pieces/cm² or less.

(2) In the SiC epitaxial wafer according to the aspect, in the epitaxial layer, a basal plane dislocation density in a first region on the SiC single crystal substrate side may be higher than a basal plane dislocation density in a second region on the outer surface side.

(3) In the SiC epitaxial wafer according to the aspect, the SiC single crystal substrate and the epitaxial layer may have the same conductivity type, the epitaxial layer may include a buffer layer and a drift layer from the SiC single crystal substrate side in this order, a carrier concentration of the buffer layer may be higher than a carrier concentration of the drift layer, and the buffer layer may include the first region.

(4) In the SiC epitaxial wafer according to the aspect, a thickness of the first region may be 1 μm or less.

(5) In the SiC epitaxial wafer according to the aspect, a diameter of the SiC single crystal substrate may be 150 mm or more.

(6) In the SiC epitaxial wafer according to the aspect, a thickness of the epitaxial layer may be 10 μm or more.

(7) A method for producing a SiC epitaxial wafer according to an aspect of the present invention includes a step of crystal-growing an epitaxial layer on a SiC single crystal substrate of which a main surface has an off-angle of 0.4° to 5° with respect to (0001) plane, in which the step of crystal-growing an epitaxial layer includes: a first step of epitaxially growing SiC on the SiC single crystal substrate while a growth rate is gradually increased from a first growth rate toward a second growth rate having a growth rate of 50 μm/h or more; and a second step of epitaxially growing SiC at a growth rate of 50 μm/h or more.

(8) In the method for producing a SiC epitaxial wafer according to the aspect, in the first step, an increase rate of the growth rate may be 0.1 μm/(h·sec) to 2.0 μm/(h·sec).

### Effects of the Invention

According to the method for producing a SiC epitaxial wafer according to the aspect of the present invention, it is possible to make an epitaxial layer have a basal plane dislocation density of 0.1 pieces/cm² or less, that is a density of basal plane dislocations extending from a SiC single crystal substrate to an outer surface, and an intrinsic 3C triangular defect density of 0.1 pieces/cm² or less.

In addition, in the SiC epitaxial wafer according to the aspect of the present invention, a low basal plane dislocation defect density having a significant effect on a device operation of a SiC device, and a higher device yield (yield ratio) and quality can be achieved.

### BRIEF DESCRIPTION OF THE DRAWINGS

FIG. 1 is a schematic sectional view of a SiC epitaxial wafer for showing a basal plane dislocation and a threading edge dislocation.

FIG. 2 is a view schematically showing behaviors of dislocations at an interface between a SiC single crystal substrate and an epitaxial layer, and inside the epitaxial layer.

FIG. 3 is a schematic view showing that effects on a SiC device vary depending on a timing of conversion from the basal plane dislocation into the threading edge dislocation.

FIG. 4 is a photoluminescence image of an intrinsic 3C triangular defect identified by a photoluminescence method.

FIG. 5 is a graph schematically showing a method for producing a SiC epitaxial wafer according to the present embodiment.

FIG. 6 is a graph showing a basal plane dislocation density included in a 4-inch SiC epitaxial wafer prepared with various growth rates of the epitaxial layer.

FIG. 7 is a graph showing a basal plane dislocation density included in a 6-inch SiC epitaxial wafer prepared with various growth rates of the epitaxial layer.

### EMBODIMENTS FOR CARRYING OUT THE INVENTION

Hereinafter, a SiC epitaxial wafer and a method for producing the SiC epitaxial wafer according to the present embodiment will be described in detail with reference to the appropriate drawings. In the drawings used in the following descriptions, for ease of understanding the features of the present invention, characteristic portions may be enlarged for convenience, and the dimensional ratio and the like of each constituent element may be the same or different from the actual dimensions. The materials, dimensions, and the like shown in the following descriptions are merely examples, and the present invention is not limited thereto and can be performed in appropriately modified manners in a range having no change the requirements (features) thereof.

(Basal Plane Dislocation (BPD), Threading Edge Dislocation (TED))

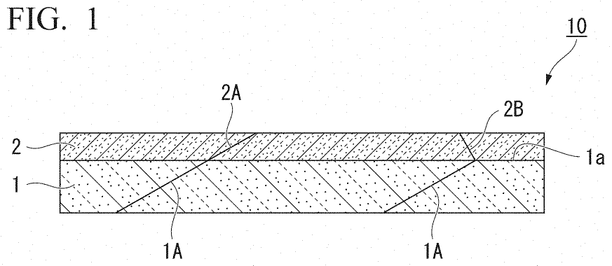

FIG. 1 is a schematic sectional view of a SiC epitaxial wafer for showing a basal plane dislocation and a threading edge dislocation.

A SiC epitaxial wafer 10 shown in FIG. 1 includes an epitaxial layer 2 disposed on a SiC single crystal substrate 1.

A basal plane dislocation (BPD) 1A exists in the SiC single crystal substrate 1. The basal plane dislocation literally means a dislocation existing in (0001) plane (c-plane) which is a basal plane of the SiC single crystal. In general, the SiC single crystal substrate 1 is provided with a growth surface 1a which is a surface having an offset-angle in a direction from (0001) to <11-20>. Therefore, the basal plane dislocation 1A in FIG. 1 is inclined with respect to the growth surface 1a.

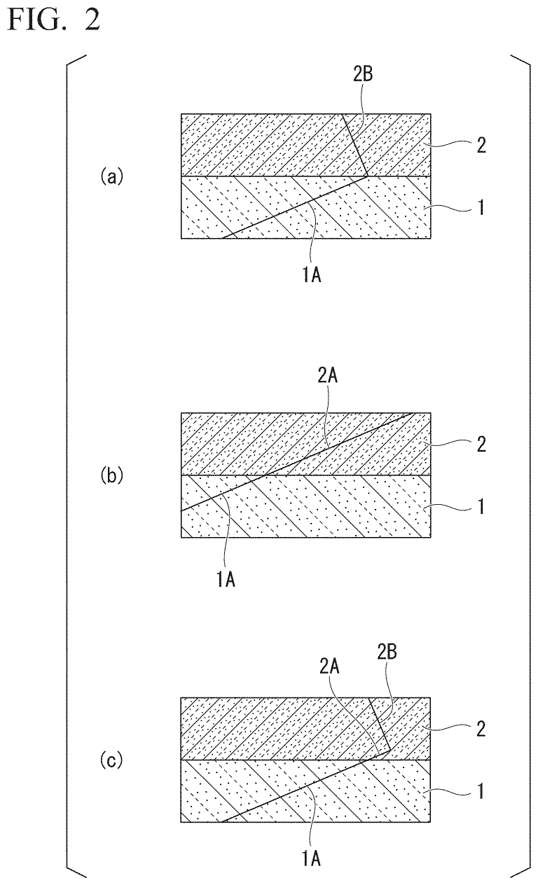

The basal plane dislocation 1A in the SiC single crystal substrate 1 has an effect on the epitaxial layer 2 when the epitaxial layer 2 is epitaxially grown, and the dislocation exhibits the following three behaviors in the epitaxial layer 2. FIG. 2 is a view schematically showing behaviors of dislocations at an interface between the SiC single crystal substrate 1 and the epitaxial layer 2 and inside the epitaxial layer 2.

A first behavior is a behavior in which the basal plane dislocation 1A is converted into a threading edge dislocation (TED) 2B at the interface between the basal plane dislocation 1A and the epitaxial layer 2, as shown in FIG. 2(a).

A second behavior is a behavior in which the basal plane dislocation 1A is transferred into the epitaxial layer 2 with no change, as shown in FIG. 2(b). The dislocation transferred into the epitaxial layer 2 becomes a basal plane dislocation 2A.

A third behavior is a behavior in which the basal plane dislocation 2A is converted into the threading edge dislocation 2B inside the epitaxial layer 2, as shown in FIG. 2(c). The behavior is likely to occur, for example, in the case where a growth condition is changed in a process of growing the epitaxial layer 2.

The basal plane dislocation and the threading edge dislocation have the same Burgers vector and are convertible to each other. The threading edge dislocation is a crystal defect in which a Burgers vector indicating a displacement direction of the crystal is orthogonal to a dislocation line. The crystal defect has a shape in which one extra atomic plane is inserted into a perfect crystal surface in a blade shape.

The basal plane dislocation 2A has a more significant negative effect on a SiC device than that of the threading edge dislocation 2B. For example, in the case where a current flows in a bipolar device including a basal plane dislocation in a forward direction, defects expand while forming Shockley-type stacking faults, and thus characteristics of the device in the forward direction are degraded.

Therefore, among three behaviors, the first behavior shown in FIG. 2(a) has the smallest effect on the SiC device. On the other hand, among three behaviors, the second behavior shown in FIG. 2(b) has the largest effect on the SiC device.

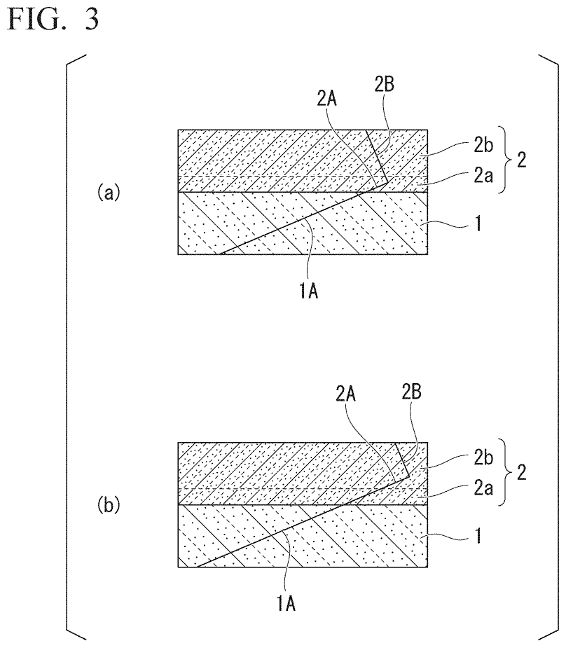

In a case of the third behavior shown in FIG. 2(c), an effect on the SiC device largely varies depending on a timing at which the basal plane dislocation 2A is converted into the threading edge dislocation 2B. FIG. 3 is a schematic view showing an effect on the SiC device which varies depending on a timing of conversion from the basal plane dislocation 2A into the threading edge dislocation 2B.

The SiC epitaxial layer 2 may include a buffer layer 2a and a drift layer 2b from the SiC single crystal substrate 1 side in this order. The drift layer 2b is a layer on which a SiC device is formed, and the buffer layer 2a is a layer for reducing a difference in a carrier concentration between the drift layer 2b and the SiC single crystal substrate 1. A difference between the buffer layer 2a and the drift layer 2b can be clearly determined by a difference in a carrier concentration therebetween. In general, the drift layer 2b has a carrier concentration lower than that of the buffer layer 2a.

The drift layer 2b is a layer on which the SiC device is formed, and in the case where the basal plane dislocation 2A is included in the layer, the SiC device is negatively affected. That is, as shown in FIG. 3(b), in the case where a conversion from the basal plane dislocation 2A into the threading edge dislocation 2B occurs in the drift layer 2b, the wafer is not accepted as the SiC epitaxial wafer 10 used for the SiC device.

On the other hand, the buffer layer 2a is a layer for adjusting the growth conditions. Even though the basal plane dislocation 2A is included in this layer, the SiC device is not directly negatively affected. In other words, as shown in FIG. 3(a), in the case where a conversion from the basal plane dislocation 2A into the threading edge dislocation 2B occurs in the buffer layer 2a, the wafer is accepted as the SiC epitaxial wafer 10 used for the SiC device.

As described above, in order to avoid affecting the SiC device, it is required to convert the basal plane dislocation 1A in the SiC single crystal substrate 1 into the threading edge dislocation 2B with high efficiency in a process of stacking the epitaxial layer 2. Furthermore, the timing of conversion from the basal plane dislocation into the threading edge dislocation is required to be a timing of conversion at the interface between the SiC single crystal substrate 1 and the epitaxial layer 2 as shown in FIG. 2(a), and a timing of conversion inside the buffer layer 2a of the epitaxial layer 2 as shown in FIG. 3(a).

The basal plane dislocations 2A and the threading edge dislocations 2B can be identified from a shape of pits generated by etching a surface selectively and X-ray topographic images of dislocations. The method using selective etching corresponds to a destructive inspection and cannot be performed non-destructively. In addition, it is difficult to measure the entire surface of a substrate using X-ray topography.

Therefore, it is preferable that a detection is performed by using a photoluminescence image in which photoluminescence light is used, and defects glow with the photoluminescence light when exposed to ultraviolet light. The basal plane dislocation 2A glows with light having a wavelength of 700 nm or more when irradiated with ultraviolet light.

By using the photoluminescence image, it is possible to detect aspects having a negative effect on the device thoroughly. As the aspects having the negative effect on the device, there are the case where the basal plane dislocation 1A is not converted and is transferred into the epitaxial layer 2 with no change (FIG. 2(b)), and the case where the basal plane dislocation 2A is converted into the threading edge dislocation 2B in the drift layer 2b (FIG. 3(b)).

In the case shown in FIG. 2(a), the dislocation included in the epitaxial layer 2 is only the threading edge dislocation 2B, and does not generally glow with the light having a wavelength of 700 nm or more. Even though there is a case where a part corresponding to an inclined plane of stacking faults seen from a stacking direction glows, these defects are distinguishable from the image.

Further, in the case shown in FIG. 3(a), since the basal plane dislocation 2A exists in the buffer layer 2a having a high carrier concentration, the photoluminescence light is scattered and difficult to detect.

That is, in a case of using the photoluminescence image, the number of basal plane dislocations 2A to be controlled can be counted.

(Intrinsic 3C Triangular Defect)

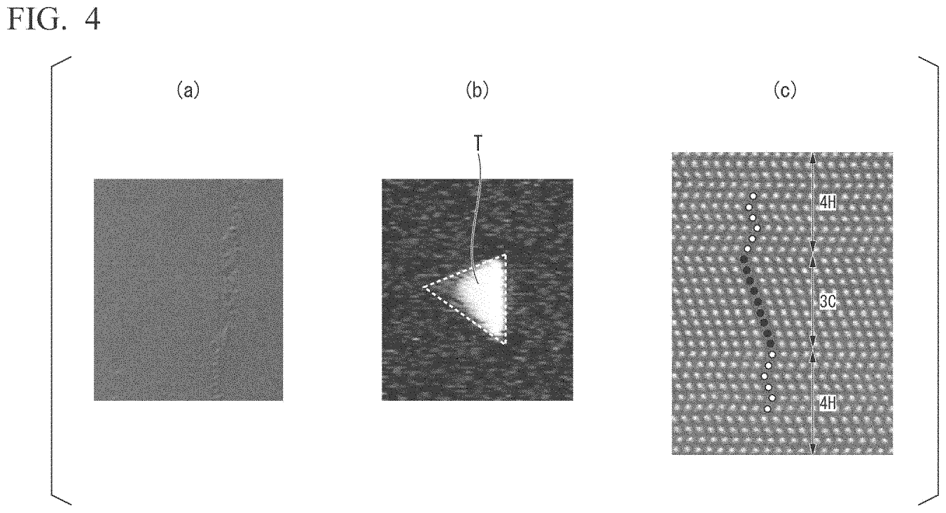

FIG. 4 shows the results obtained by measuring an intrinsic 3C triangular defect. FIG. 4(a) is a surface microscope image, FIG. 4(b) is a photoluminescence image, and FIG. 4(c) is a transmission electron microscope (TEM) image. In FIG. 4(b), an outer periphery of the intrinsic 3C triangular defect T is bordered by dotted line for ease understanding.

The intrinsic 3C triangular defect T means a defect which glows with the photoluminescence light having a triangular shape and a wavelength of 540 nm to 600 nm when irradiated with ultraviolet light.

The intrinsic 3C triangular defect T is slightly different from a so-called surface triangular defect in definition. The surface triangular defect means a defect having a triangular shape when seen with an optical microscope, and only means the defect seen on the surface of the epitaxial layer 2. On the other hand, the intrinsic 3C triangular defect T also includes a defect determined by the photoluminescence image and included inside the epitaxial layer 2. Therefore, even though the defect having a triangular shape is not visible with the optical microscope (FIG. 4(a)), the defect having a triangular shape is captured in the photoluminescence image (FIG. 4(b)).

The intrinsic 3C triangular defect T is a defect formed along a step-flow growth direction (<11-20> direction) toward a direction such that an apex of the triangle and an opposite side (base side) thereof are arranged from upstream to downstream. The intrinsic 3C triangular defect T is formed such that a layer having the 3C polytype expands from a foreign matter (particle), which exists on the SiC single crystal substrate before epitaxial growth as a starting point, along the offset-angle of the substrate and is exposed to the surface of the epitaxial layer 2. In a portion where the intrinsic 3C triangular defect T exists, the atomic arrangement in the transmission electron microscope image (FIG. 4 (c)) changes. Specifically, as shown in FIG. 4(c), it can be seen that a 3C layer of 9 bilayers is mixed in the 4H crystal period.

In other words, the intrinsic 3C triangular defect T is a defect existing inside the epitaxial layer 2 and is a defect having a triangular shape and including the 3C polytype therein. Since the portion where SiC of 3C polytype is formed differs in electrical characteristics from the normal epitaxial layer consisting of the other 4H polytype, the SiC device containing the intrinsic 3C triangular defects becomes defective.

In addition, since the area occupied by the defect increases as a length of the base side of the intrinsic 3C triangular defect increases, the intrinsic 3C triangular defect is easily detected. Therefore, in order to detect the intrinsic 3C triangular defects thoroughly, it is preferable to increase the crystal growth rate of the epitaxial layer 2 or to increase the thickness of the epitaxial layer 2.

For example, in the case where the crystal growth rate of the epitaxial layer 2 is less than 50 μm/h, the thickness of the epitaxial layer 2 is preferably 30 μm or more, and in the case where the crystal growth rate of the epitaxial layer 2 is 50 μm/h or more, the thickness of the epitaxial layer 2 is preferably 10 μm or more. The upper limit of the thickness of the epitaxial layer 2 may be 400 μm or less.

(Method for Producing SiC Epitaxial Wafer)

In a method for producing a SiC epitaxial wafer 10 according to the present embodiment, an epitaxial layer 2 is crystal-grown on a SiC single crystal substrate 1 of which a main surface has an off-angle of 0.4° to 5° with respect to (0001) plane.

First, the SiC single crystal substrate 1 is prepared. Various methods for preparing the SiC single crystal substrate 1 are selectively used (the method for preparing the SiC single crystal substrate 1 is not particularly limited). For example, the SiC single crystal substrate can be obtained by slicing a SiC ingot obtained by a sublimation method or the like.

In the SiC single crystal substrate 1, a basal plane dislocation 1A exists along (0001) plane (c-plane). The number of basal plane dislocations 1A exposed to a growth surface 1a of the SiC single crystal substrate 1 is preferably as small as possible, but is not particularly limited. At the current level of technology, the number of basal plane dislocations 1A existing on the surface (growth surface) of a 6-inch SiC single crystal substrate 1 is about 1000 to 5000 per 1 cm².

Next, the epitaxial layer 2 is epitaxially grown on the SiC single crystal substrate 1 to prepare the SiC epitaxial wafer 10. The epitaxial layer 2 is obtained, for example, by step-flow growth (lateral growth from atomic step) on the growth surface 1a of the SiC single crystal substrate 1 by a chemical vapor deposition (CVD) method or the like.

As a Si-based gas, silane, silane chloride such as trichlorosilane, dichlorosilane, and the like can be used. As a C-based gas, propane, ethylene, and the like can be used. As a growth temperature, in general, a temperature applied for 4H-SiC epitaxial growth can be used.

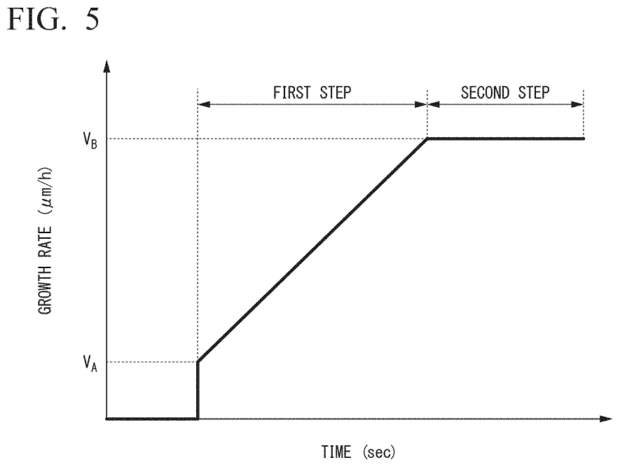

The process of growing the epitaxial layer 2 is separated into a first step and a second step. FIG. 5 is a diagram schematically showing growth conditions for growing the epitaxial layer 2.

As shown in FIG. 5, in the first step, SiC is epitaxially grown on the SiC single crystal substrate 1 while the growth rate is gradually increased (ramping) from a first growth rate V_{A} to a second growth rate V_{B}. That is, in the first step, an amount of raw material gas (a C-based raw material, a Si-based raw material, and the like) supplied into a growth space is gradually increased. The first growth rate V_{A} is a growth rate at the start of epitaxial growth in the first step. The second growth rate V_{B} is a growth rate at the end of the first step. By gradually increasing the amount of raw material gas supplied into the growth space in the first step, the generation of intrinsic 3C triangular defects is suppressed.

The intrinsic 3C triangular defect is formed with the foreign matter existing on the SiC single crystal substrate as a nucleus. Examples of the nucleus include silicon droplets produced by nucleation of a part of the raw materials in the growth space or on the surface of the SiC single crystal substrate, SiC precipitation of a polytype different from a polytype of substrate, or the like.

Nucleation of the raw materials, such as silicon droplets or SiC precipitation of a polytype different from a polytype of substrate, is caused by the inconsistent raw material ratio in the growth space. That is, nucleation of the raw materials is caused by the inconsistent C/Si ratio in the growth space. For example, in the case where the C/Si ratio in the growth space decreases (the amount of Si becomes excessive), silicon droplets are likely to occur. In addition, in the case where the C/Si ratio in the growth space increases (the amount of C becomes excessive), step bunching is likely to be formed on the growth surface, the terrace width increases accordingly, and then nucleation of SiC having a polytype different from a polytype of substrate is likely to occur.

In addition, in the case where the amount of raw material gas existing in the growth space is large, the total amount of atoms is large. Therefore, the probability in which atoms are associated increases. In this reason, nucleation occurs even though the C/Si ratio is slightly inconsistent.

In addition, the C/Si ratio is likely to be inconsistent at an initial stage of crystal growth. This is because a C-based raw material and a Si-based raw material reach the substrate at different times even though the input ratio of the raw material is controlled. In other words, in an initial stage of epitaxial growth, the theoretical value of the C/Si ratio may be different from the effective value of the C/Si ratio.

Therefore, in the case where a large amount of raw material gas is supplied at once without gradually increasing the flow rate of the raw materials to be introduced, the probability of the generation of intrinsic 3C triangular defects increases. This tendency is remarkable under growth conditions in which the second growth rate V_{B} is very high. The high growth rate is due to the fact that the amount of supplied raw material gas is very large.

The first growth rate V_{A} in the first step is preferably 0.1 μm/h to 10 μm/h, and more preferably 1 μm/h to 5 μm/h. Within the range, epitaxial growth can be performed by controlling the C/Si ratio with the effective value.

An increase rate of the growth rate from the first growth rate V_{A} to the second growth rate V_{B} is preferably 0.1 μm/(h·sec) to 2.0 μm/(h·sec), and more preferably 0.2 μm/(h·sec) to 1.0 μm/(h·sec).

The increase rate of the growth rate in the first step corresponds to the rate of change of the growth rate per unit time, and corresponds to the inclination of the graph in FIG. 5. In the case where the increase rate of the growth rate is within the above-described range, rapid changes in the flow rate of the supplied raw materials are not observed, and significant disorder of the C/Si ratio is avoided. That is, nucleation can be suppressed.

The C/Si ratio in the first step is preferably 0.8 to 1.2 and more preferably 0.9 to 1.1. Since the epitaxial layer grown in the first step is in contact with the SiC single crystal substrate 1, it is preferable to set the C/Si ratio according to the C/Si ratio of elements constituting the SiC single crystal substrate 1.

In the second step, SiC is epitaxially grown at a growth rate of 50 μm/h or more. The growth rate in the second step may be 50 μm/h or more, and is preferably 60 μm/h or more. The growth rate in the second step may be retained as the second growth rate V_{B} finally reached in the first step or may be varied.

When the epitaxial layer 2 is formed, most of the basal plane dislocations 1A of the SiC single crystal substrate 1 are converted into the threading edge dislocations 2B at the interface between the SiC single crystal substrate 1 and the epitaxial layer 2 (FIG. 2(a)) or during the first step (FIG. 3(a)).

This is because the energy of dislocations is reduced and stabilized in the case where the basal plane dislocation 1A in the SiC single crystal substrate 1 is converted into the threading edge dislocation 2B to shorten the dislocation length rather than in the case where the basal plane dislocation 1A is transferred into the epitaxial layer 2 with no change and becomes the basal plane dislocation 2A. Furthermore, a part of basal plane dislocations 1A are transferred into the epitaxial layer 2 with no change and become the basal plane dislocations 2A which result in the device killer defects.

In order to enhance the conversion efficiency from the basal plane dislocation 1A into the threading edge dislocation 2B and to suppress the basal plane dislocations 2A which result in the device killer defects, it is preferable to accelerate the growth rate of the epitaxial layer in the second step. In the case where the growth rate in the second step is 50 μm/h or more, the density of basal plane dislocations 2A extending from the SiC single crystal substrate 1 without being converted into threading edge dislocations 2B can be 0.1 pieces/cm² or less even in the SiC epitaxial wafer 10 having a size of 6 inches or more.

In the SiC epitaxial wafer 10 having a size of “6 inches or more”, it is very important that the density of basal plane dislocations 2A extending from the SiC single crystal substrate 1 without being converted into the threading edge dislocations 2B be 0.1 pieces/cm² or less. With regard to the conventional SiC epitaxial wafer having a size of 4 inches or less, a SiC epitaxial wafer in which the basal plane dislocation density is relatively low is being reported. However, there is no report on a SiC epitaxial wafer having a size 6 inches or more. With regard to the SiC epitaxial wafer having a size of 6 inches or more, conditions for forming a film on the SiC single crystal substrate vary, and thus it is difficult to obtain the same result as in the case where the size is 4 inches.

In the SiC epitaxial wafer 10 having a size of 4 inches or less, in the case where the growth rate of the epitaxial layer 2 is less than 50 μm/h, there is a case where the basal plane dislocation density is 0.1 pieces/cm² or less. Examples of this case include a case where the basal plane dislocation 1A of the SiC single crystal substrate 1 itself is small, and a case where the film forming conditions are fixed to specific conditions.

However, in practice, a state of the SiC single crystal substrate 1 is not identical, and is different for each batch or wafer. In addition, the film forming conditions also need to be changed for various reasons. Therefore, it is difficult to stably reduce the basal plane dislocation density even in the SiC epitaxial wafer 10 having a size of 4 inches or less.

The C/Si ratio in the first step and the second step is preferably 0.8 to 1.4. In the case where the C/Si ratio is in the above-described range, an epitaxial wafer having preferable characteristics as a device operation layer can be obtained. For example, it is preferable to set the C/Si ratio to a low value in a case of making pits caused from the dislocations shallow, and to set the C/Si ratio to a high value in a case of making the background of n-type doping decrease.

In addition, in the second step, it is preferable to introduce gas having Cl element (for example, HCl gas) or the like into a film formation space together with the raw material gas. By introducing the gas having the Cl element together with the raw material gas, SiClₓ is formed on the growth surface 1a, and the generation of Si droplets can be further suppressed.

Furthermore, it is preferable to reduce the gas pressure in a film forming environment. Specifically, the gas pressure is preferably in a range of 1 Torr to 100 Torr, and more preferably in a range of 1 Torr to 50 Torr. In the case where the gas pressure in the film forming environment is in this range, it is possible to suppress the nucleation of SiC in the gas phase and attaching of the generated nucleus on the SiC single crystal substrate while sufficiently securing the growth rate of the epitaxial layer. That is, it is possible to avoid the generation of the foreign matter which becomes the starting point of triangular defects.

In the second step, the growth rate of the epitaxial layer 2 is preferably set to 75 μm/h or more, more preferably set to 300 μm/h or less. In the case where the growth rate of the epitaxial layer 2 is set to 75 μm/h or more, the conversion efficiency from the basal plane dislocation 1A into the threading edge dislocation 2B can be further increased. Therefore, the basal plane dislocation density can be stably 0.1 pieces/cm² or less. On the other hand, in the case where the growth rate is 300 μm/h or less, the inconsistency of the C/Si ratio is suppressed, and therefore the generation of triangular defects can be suppressed.

In addition, before growing the epitaxial layer 2, a surface treatment such as etching, polishing, or the like may be performed on the growth surface 1a of the SiC single crystal substrate 1. By performing etching or polishing on the growth surface 1a of the SiC single crystal substrate 1 before growing the epitaxial layer 2, damage (crystal distortion or foreign matter) and the like remaining on the growth surface 1a can be removed.

The etching is preferably performed in a film forming chamber. As etching gas, hydrogen gas, hydrogen chloride gas, silane (SiH₄) gas or the like can be used. Chemical mechanical polishing (CMP) or the like can be used for the polishing.

Furthermore, the buffer layer 2a may be formed at the initial stage of growth of the epitaxial wafer 10. The buffer layer 2a is a portion where the carrier concentration is higher than the carrier concentration of the drift layer 2b of the epitaxial layer 2. In the case where the buffer layer 2a is included, the carrier concentration between the SiC single crystal substrate 1 and the drift layer 2b can be adjusted. The carrier concentration of the buffer layer can be set to 1×10¹⁷ cm⁻³ to 1×10¹⁹ cm⁻³. The carrier concentration of the drift layer can be set to 1×10¹⁴ cm⁻³ to 1×10¹⁷ cm⁻³. Nitrogen can be used as a dopant of an n-type conductive SiC epitaxial layer, and N₂ can be used as dopant material gas.

As described above, in the method for producing the SiC epitaxial wafer according to one aspect of the present invention, by increasing the growth rate, the conversion efficiency from the basal plane dislocation 1A into the threading edge dislocation 2B is increased, and the density of basal plane dislocations 2A extending from the SiC single crystal substrate 1 in the epitaxial wafer without being converted into threading edge dislocations 2B can be 0.1 pieces/cm² or less.

Furthermore, by setting the growth rate to a predetermined rate or higher, the basal plane dislocation density can be stably set to 0.1 pieces/cm² or less with high reproducibility even under another SiC single crystal substrate or another film forming condition.

Furthermore, the intrinsic 3C triangular defect, which is likely to be generated by increasing the growth rate of the epitaxial layer, can be reduced by setting the film forming conditions and the like to predetermined conditions.

(SiC Epitaxial Wafer)

A SiC epitaxial wafer according to the present embodiment is obtained by the above-described manufacturing method. The SiC epitaxial wafer according to the present embodiment includes the SiC single crystal substrate 1 and the SiC epitaxial layer 2 as shown in FIG. 1. The SiC epitaxial layer 2 may be directly provided on the SiC single crystal substrate 1.

In the SiC single crystal substrate 1, the main surface has an off-angle of 0.4° to 5° with respect to (0001) plane. In the case where the off-angle is in the above-described range, the epitaxial layer 2 can be grown while maintaining the off-angle required for the device.

The basal plane dislocation density that is the density of basal plane dislocations extending from the SiC single crystal substrate 1 to the outer surface of the epitaxial layer 2 is 0.1 pieces/cm² or less, and the intrinsic 3C triangular defect density is 0.1 pieces/cm² or less.

The basal plane dislocations are detected by a photoluminescence method. By using light having a wavelength of 400 nm or less as excitation light, a linear defect which glows with the light having a wavelength of 700 nm or more and extends in the step-flow direction in epitaxial growth is detected as the basal plane dislocation. Then, the number of basal plane dislocations detected in the SiC epitaxial wafer is counted and divided by an area of the SiC epitaxial wafer to obtain the basal plane dislocation density.

The intrinsic 3C triangular defects are also detected by the photoluminescence method. By using light having a wavelength of 400 nm or less as excitation light, a triangular defect which glows with the light having a wavelength of 540 nm to 600 nm is detected as the intrinsic 3C triangular defect. Then, the number of basal plane dislocations detected in the SiC epitaxial wafer is counted and divided by an area of the SiC epitaxial wafer to obtain the intrinsic 3C triangular defect density.

Herein, “the density of basal plane dislocations extending from the SiC single crystal substrate 1 to the outer surface” means that in principle, the density of basal plane dislocations 2A extending from the SiC single crystal substrate 1 to the outer surface without being converted into threading edge dislocations 2B, as shown in FIG. 2(b).

The basal plane dislocations 2A existing in the epitaxial layer 2 have two patterns (embodiments). One pattern is a basal plane dislocation 2A which extends from the SiC single crystal substrate 1 to the outer surface without being converted into the threading edge dislocation 2B as shown in FIG. 2(b), and the other pattern is a basal plane dislocation 2A which is converted into the threading edge dislocation 2B inside the epitaxial layer 2, as shown in FIGS. 3(a) and 3(b).

The former pattern is measured on the basis of a photoluminescence image, and the latter pattern is not measured in principle. As shown in FIG. 3(a), in the case where the basal plane dislocation 2A is converted into the threading edge dislocation 2B in the buffer layer 2a, the basal plane dislocation 2A may not be measured sufficiently because the photoluminescence light is scattered. In addition, since the drift layer 2b shown in FIG. 3(b) grows at a high rate in the second step, in principle, the basal plane dislocation 2A may not be converted into the threading edge dislocation 2B in the drift layer 2b.

Even in the case where a part of the basal plane dislocations 2A converted into the threading edge dislocations 2B in the epitaxial layer 2 is measured at the same time, the excessive amount of basal plane dislocations 2A are measured, and thus the density of basal plane dislocations 2A extending from the SiC single crystal substrate 1 to the outer surface is still 0.1 pieces/cm² or less.

In the case where the basal plane dislocation density is low, a yield (yield ratio) for producing SiC devices from one SiC epitaxial wafer can be increased. In addition, in the case where the intrinsic 3C triangular defect density is low, a proportion of the portions consisting of the 3C polytype which have electrical characteristics different from those of the normal epitaxial layer consisting of the 4H polytype becomes small. Therefore, this contributes to the improvement of the effective area and yield of the SiC devices.

The diameter of the SiC single crystal substrate is preferably 150 mm or more (6 inches or more). With regard to the SiC epitaxial wafer having a size of 6 inches or more, the SiC epitaxial wafer in which the basal plane dislocation density and the intrinsic 3C triangular defect are in the above-described ranges is found for the first time.

It is important that the SiC epitaxial wafer has a size of 6 inches or more. This is because the number of SiC devices that can be manufactured from a single SiC epitaxial wafer can be increased, and the cost of the SiC devices can be reduced. The SiC device provides very good performance, but there is a problem that the SiC devices are more expensive than Si devices. However, a large-sized SiC device having low basal plane dislocation density leads to a significant cost reduction.

In the epitaxial layer 2, the basal plane dislocation density of a first region on the SiC single crystal substrate 1 side is higher than the basal plane dislocation density of a second region on the outer surface side. This is because the crystal growth conditions of the epitaxial layer 2 are separated into the first step and the second step.

Specifically, the epitaxial layer 2 has two opposing main surfaces, the first region is located on a first main surface side in contact with the SiC single crystal substrate 1, and the second region is located on a second main surface side facing the outer surface.

As the growth rate is increased, the basal plane dislocation 2A is likely to be converted into the threading edge dislocation 2B. In the first step of gradually increasing the growth rate, the conversion rate gradually increases. In a range of the growth rate of more than 50 μm/h, most BPDs can be converted into TEDs. That is, the basal plane dislocation density of the epitaxial layer grown in the second step is relatively lower than the basal plane dislocation density of the epitaxial layer grown in the first step.

Therefore, the epitaxial layer grown in the first step corresponds to the first region, and the epitaxial layer grown in the second step corresponds to the second region. Since the growth conditions between the first and second steps are changed gradually, a clear crystal boundary cannot be seen. However, these regions can be identified as regions which have the different basal plane dislocation densities.

In the case where the SiC single crystal substrate 1 and the epitaxial layer 2 have the same conductivity type, the epitaxial layer 2 may include the buffer layer 2a and the drift layer 2b from the SiC single crystal substrate 1 side in this order. Specifically, the buffer layer 2a is located on the first main surface side in contact with the SiC single crystal substrate 1, and the drift layer 2b is located on the second main surface side facing the outer surface. By providing the buffer layer, a difference in carrier concentration between the SiC single crystal substrate 1 and the drift layer 2b can be adjusted.

The first region is preferably included in the buffer layer 2a. As described above, the first region has a relatively high basal plane dislocation density in the epitaxial layer 2. In the case where the basal plane dislocation 2A exists in the buffer layer 2a, an effect on the SiC device can be reduced. That is, in the manufacturing process, the first step is preferably performed in the process of forming the buffer layer 2a.

It is better that the BPDs are not extended to the epitaxial layer 2 as much as possible. Therefore, the thickness of the first region is preferably 1 μm or less. The lower limit of the thickness of the first region is not particularly limited, and is preferably more than 0 μm. The thickness of the first region is determined from the basal plane dislocation density which is measured while grinding the epitaxial layer 2 in the thickness direction. The thickness, from a ground surface in which the basal plane dislocation density is 10 or more times than the basal plane dislocation density of the outer surface, to the SiC single crystal substrate 1 corresponds to the thickness of the first region. In other words, the basal plane dislocation density of the first region is 10 or more times greater than the basal plane dislocation density of the second region. In the epitaxial layer 2, a section (portion) other than the first region is the second region.

The thickness of the epitaxial layer 2 is preferably 10 μm or more. The intrinsic 3C triangular defect is more easily found in a thicker epitaxial layer 2. Therefore, in the case where the thickness of the epitaxial layer 2 is in the above-described range, the intrinsic 3C triangular defects can be identified thoroughly.

A shape of the SiC epitaxial wafer is not particularly limited. The SiC epitaxial wafer may have a round shape which is generally used or a shape provided with a notch such as an oriental flat (OF).

In the SiC epitaxial wafer according to the present embodiment, amounts of the basal plane dislocations (BPD) and the intrinsic 3C triangular defects which result in the device killer defects of the SiC device are small, and the quality of the SiC device is increased.

In addition, since a large current of 100 A-class is treated in one device in a module for automobiles and the like, a SiC chip (a substrate of the SiC device) produced from a SiC epitaxial wafer has a large size of 10 mm square. In such a large-sized SiC chip, since an effect of the basal plane dislocation density on the yield is extremely high, it is extremely important to reduce the basal plane dislocation density.

### EXAMPLES

Hereinafter, examples of the present invention will be described. However, the present invention is not limited thereto.

### Examination of Basal Plane Dislocation

### Examples 1-1 to 1-5

A SiC single crystal substrate having a size of 4 inches was prepared. The prepared SiC single crystal substrate was a 4H polytype, and a main surface had an off-angle of 4°.

Next, the SiC single crystal substrate was introduced into a growth furnace, and gas etching was performed on a growth surface using hydrogen gas. The etching temperature was set to a temperature the same as the epitaxial growth temperature.

Next, an epitaxial layer was grown on a surface of the etched 4H-SiC single crystal substrate while supplying silane and propane as raw material gas, and hydrogen as carrier gas. A first growth rate V_{A} in a first step was set to 4 μm/h, and a second growth rate V_{B} was set to 75 μm/h. The maximum increase rate of the growth rate from the first growth rate V_{A} to the second growth rate V_{B} in the first step was set to 0.4 μm/(h·sec).

The maximum increase rate of the growth rate was obtained using a calculation method as follows. The flow rate of silicon-based raw material gas when a growth rate reached a predetermined growth rate V was set to x (sccm), and the maximum increase rate of the flow rate of silicon-based raw material gas was set to y (sccm/sec). Then, according to the following Calculation Expression (1), the maximum increase rate of the growth rate was determined.

“Maximum Increase Rate of Growth Rate”=y÷x×V (1)

A flow rate of a carbon-based raw material was increased as the flow rate of a silicon-based raw material was increased within a C/Si ratio of 0.8 to 1.4. The C/Si ratio in the first step was set to 1.0, and the C/Si ratio in the second step was set to 1.2.

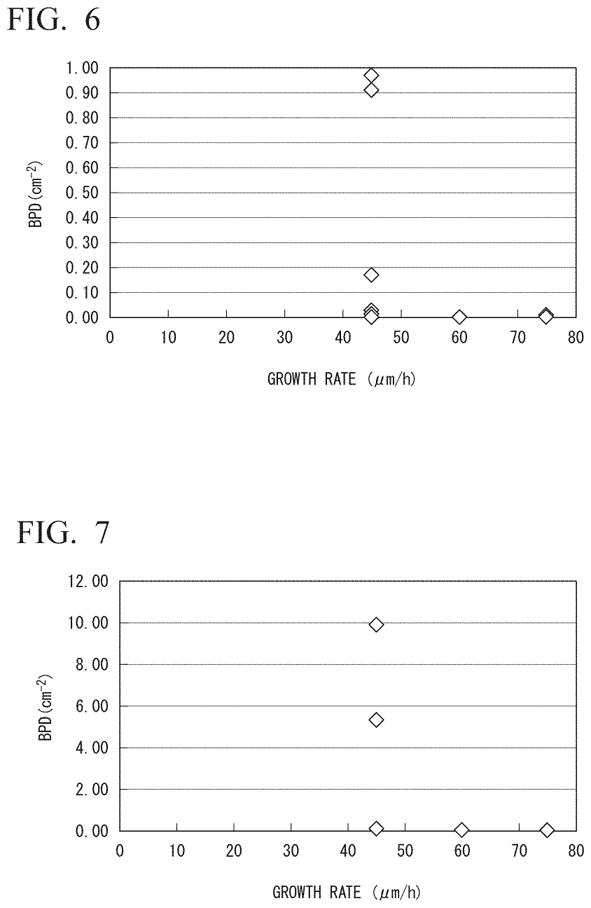

The basal plane dislocation density of the prepared SiC epitaxial wafer was evaluated using a photoluminescence imaging apparatus manufactured by Photon Design Co. Ltd. The obtained results are shown in Table 1 and FIG. 6. Furthermore, since the number of basal plane dislocations 1A included in the SiC single crystal substrate 1 was different for each sample, four different samples were examined under the same condition. The results are shown as Examples 1-2 to 1-5.

### Example 2-1

Example 2-1 is different from Example 1-1 in that the second growth rate V_{B} was set to 60 μm/h. The other conditions were the same as those in Example 1-1. A basal plane dislocation density of a SiC epitaxial wafer obtained in Example 2-1 was also evaluated. The obtained results are shown in Table 1 and FIG. 6.

### Comparative Examples 1-1 to 1-6

Comparative Example 1-1 is different from Example 1-1 in that the second growth rate V_{B} was 45 μm/h. The other conditions were the same as those in Example 1-1. A basal plane dislocation density of a SiC epitaxial wafer obtained in Example 1-1 was also evaluated. The obtained results are shown in Table 1 and FIG. 6. Furthermore, since the number of basal plane dislocations 1A included in the SiC single crystal substrate 1 was different for each sample, five different samples were examined under the same conditions. The results are shown as Comparative Examples 1-2 to 1-6.

TABLE 1

| | First | | | |
|---|---|---|---|---|
| | growth | Second | Maximum | Basal plane |
| | rate | growth rate | increase rate | dislocation density |
| | (μm/h) | (μm/h) | (μm/h · sec) | (pieces/cm²) |
| Example 1-1 | 4 | 75 | 0.4 | 0.00 |
| Example 1-2 | 4 | 75 | 0.4 | 0.00 |
| Example 1-3 | 4 | 75 | 0.4 | 0.05 |
| Example 1-4 | 4 | 75 | 0.4 | 0.00 |
| Example 1-5 | 4 | 75 | 0.4 | 0.01 |
| Example 2-1 | 4 | 60 | 0.4 | 0.00 |
| Comparative | 4 | 45 | 0.4 | 0.01 |
| Example 1-1 | | | | |
| Comparative | 4 | 45 | 0.4 | 0.00 |
| Example 1-2 | | | | |
| Comparative | 4 | 45 | 0.4 | 0.03 |
| Example 1-3 | | | | |
| Comparative | 4 | 45 | 0.4 | 0.97 |
| Example 1-4 | | | | |
| Comparative | 4 | 45 | 0.4 | 0.91 |
| Example 1-5 | | | | |
| Comparative | 4 | 45 | 0.4 | 0.17 |
| Example 1-6 | | | | |

### Examples 3-1 to 3-5

Example 3-1 is different from Example 1-1 in that the SiC single crystal substrate had a size of 6 inches. The other conditions were the same as those in Example 1-1.

A basal plane dislocation density of a SiC epitaxial wafer obtained in Example 3-1 was also evaluated. The obtained results are shown in Table 2 and FIG. 7. Furthermore, since the number of basal plane dislocations 1A included in the SiC single crystal substrate 1 was different for each sample, five different samples were examined under the same condition. The results are shown as Examples 3-2 to 3-5.

### Examples 4-1 to 4-3

Example 4-1 is different from Example 2-1 in that the SiC single crystal substrate had a size of 6 inches. The other conditions were the same as those in Example 2-1.

A basal plane dislocation density of a SiC epitaxial wafer obtained in Example 4-1 was also evaluated. The obtained results are shown in Table 2 and FIG. 7. Furthermore, since the number of basal plane dislocations 1A included in the SiC single crystal substrate 1 was different for each sample, three different samples were examined under the same conditions. The results are shown as Examples 4-2 and 4-3.

### Comparative Examples 2-1 to 2-3

Comparative Example 2-1 is different from Comparative Example 1-1 in that the SiC single crystal substrate had a size of 6 inches. The other conditions were the same as those in Comparative Example 1-1.

A basal plane dislocation density of a SiC epitaxial wafer obtained in Comparative Example 2-1 was also evaluated. The obtained results are shown in Table 2 and FIG. 7. Furthermore, since the number of basal plane dislocations 1A included in the SiC single crystal substrate 1 was different for each sample, three different samples were examined under the same condition. The results are shown as Comparative Examples 2-2 and 2-3.

TABLE 2

| | First | | | |
|---|---|---|---|---|
| | growth | Second | Maximum | Basal plane |
| | rate | growth rate | increase rate | dislocation density |
| | (μm/h) | (μm/h) | (μm/h · sec) | (pieces/cm²) |
| Example 3-1 | 4 | 75 | 0.4 | 0.00 |
| Example 3-2 | 4 | 75 | 0.4 | 0.02 |
| Example 3-3 | 4 | 75 | 0.4 | 0.02 |
| Example 3-4 | 4 | 75 | 0.4 | 0.00 |
| Example 3-5 | 4 | 75 | 0.4 | 0.00 |
| Example 4-1 | 4 | 60 | 0.4 | 0.02 |
| Example 4-2 | 4 | 60 | 0.4 | 0.02 |
| Example 4-3 | 4 | 60 | 0.4 | 0.10 |
| Comparative | 4 | 45 | 0.4 | 9.90 |
| Example 2-1 | | | | |
| Comparative | 4 | 45 | 0.4 | 5.33 |
| Example 2-2 | | | | |
| Comparative | 4 | 45 | 0.4 | 0.14 |
| Example 2-3 | | | | |

As shown in Tables 1 and 2, in the case where the second growth rate V_{B} was set to 50 μm/h or more, the basal plane dislocation density of the SiC epitaxial wafer was 0.1 pieces/cm² or less. On the other hand, in the case where the second growth rate V_{B} was set to less than 50 μm/h, there were cases in which the basal plane dislocation density was more than 0.1 pieces/cm². In particular, in the case where the SiC single crystal substrate had the size of 6 inches, the basal plane dislocation density was large.

### Examination of Intrinsic 3C Triangular Defect

### Example 3-1

When the SiC epitaxial wafer of Example 3-1 was irradiated with ultraviolet light, the emitted light having a wavelength of 540 nm to 600 nm was detected as photoluminescence light to measure the intrinsic 3C triangular defect density. In addition, the surface triangular defect density exposed and seen on the measured surface was also measured together with the intrinsic 3C triangular defect density by using a confocal microscope with a differential interference contrast system (SICA). The results are shown in Table 3.

### Comparative Example 3-1

Comparative Example 3-1 is different from Example 3-1 in that the first step was not performed. The other conditions were the same as those in Example 3-1. The intrinsic 3C triangular defect density and the surface triangular defect density of Comparative Example 3-1 were measured in the same manner as in Example 3-1. The results are shown in Table 3.

### Comparative Example 3-2

Comparative Example 3-2 is different from Example 3-1 in that the first step was not performed and the growth rate in the second step was set to 7 μm/h. The other conditions were the same as those in Example 3-1. The intrinsic 3C triangular defect density and the surface triangular defect density of Comparative Example 3-2 were measured in the same manner as in Example 3-1. The results are shown in Table 3.

TABLE 3

| | | | | | | | | Intrinsic 3C |
|---|---|---|---|---|---|---|---|---|
| | | | | | | Basal plane | Surface triangular | triangular defect |
| | | First | Second | Maximum | Thickness of | dislocation | defect density | density |
| | Wafer | growth rate | growth rate | increase rate | epitaxial film | density | measured by SICA | measured by PL |
| | size | (μm/h) | (μm/h) | (μm/h · sec) | (μm) | (pieces/cm²) | (pieces/cm²) | (pieces/cm²) |
| Example 3-1 | 150 mm | 4 | 75 | 0.4 | 13 | 0.00 | 0.05 | 0.00 |
| Comparative | 150 mm | 0 | 75 | 75 | 13 | 0.00 | 0.04 | 0.39 |
| Example 3-1 | | | | | | | | |
| Comparative | 150 mm | 0 | 7 | 7 | 30 | 10 | 0.01 | 0.00 |
| Example 3-2 | | | | | | | | |

As shown in Comparative Example 3-1 of Table 3, in the case where the first step was not provided, the intrinsic 3C triangular defect density was increased. Furthermore, as shown in Comparative Example 3-2 of Table 3, in the case where a crystal growth rate in the second step was set to be low, the basal plane dislocation density was increased.

On the other hand, in Example 3-1 in which the first step was performed and the epitaxial growth was performed at 75 μm/h in the second step, both the base dislocation density and the triangular defect density were 0.1 pieces/cm² or less. In addition, there was no difference in the surface triangular defect density, and it was confirmed that the SICA could not detect the intrinsic triangular defects.

### INDUSTRIAL APPLICABILITY

According to the present invention, it is possible to provide a SiC epitaxial wafer having a low basal plane dislocation density and a low intrinsic 3C triangular defect density. In particular, it is possible to provide a SiC epitaxial wafer having the low basal plane dislocation density and a diameter of 150 mm or more (6 inches or more). Therefore, the number of SiC devices that can be manufactured from one SiC epitaxial wafer can be increased, and the cost of the SiC devices can be reduced. Therefore, the present invention can be suitably applied to a SiC epitaxial wafer for SiC devices such as power devices, high-frequency devices, and high-temperature operation devices, and a method for producing a SiC epitaxial wafer.

### EXPLANATION OF REFERENCE SIGNS

1: SiC single crystal substrate
2: epitaxial layer
10: SiC epitaxial wafer
1A, 2A: basal plane dislocation
2B: threading edge dislocation
T: triangular defect

1. A SiC epitaxial wafer comprising:
a SiC single crystal substrate of which a main surface has an off-angle of 0.4° to 5° with respect to (0001) plane; and
an epitaxial layer provided on the SiC single crystal substrate,
wherein the epitaxial layer has a basal plane dislocation density of 0.1 pieces/cm² or less that is a density of basal plane dislocations extending from the SiC single crystal substrate to an outer surface and an intrinsic 3C triangular defect density of 0.1 pieces/cm² or less.

2. The SiC epitaxial wafer according to claim 1,
wherein in the epitaxial layer, a basal plane dislocation density in a first region on the SiC single crystal substrate side is higher than a basal plane dislocation density in a second region on the outer surface side.

3. The SiC epitaxial wafer according to claim 2,
wherein the SiC single crystal substrate and the epitaxial layer have the same conductivity type,
the epitaxial layer includes a buffer layer and a drift layer from the SiC single crystal substrate side in this order,
a carrier concentration of the buffer layer is higher than a carrier concentration of the drift layer, and
the buffer layer includes the first region.

4. The SiC epitaxial wafer according to claim 2,
wherein a thickness of the first region is 1 μm or less.

5. The SiC epitaxial wafer according to claim 1,
wherein a diameter of the SiC single crystal substrate is 150 mm or more.

6. The SiC epitaxial wafer according to claim 1,
wherein a thickness of the epitaxial layer is 10 μm or more.

7. A method for producing a SiC epitaxial wafer, comprising:
a step of crystal-growing an epitaxial layer on a SiC single crystal substrate of which a main surface has an off-angle of 0.4° to 5° with respect to (0001) plane,
wherein the step of crystal-growing an epitaxial layer includes:
a first step of epitaxially growing SiC on the SiC single crystal substrate while a growth rate is gradually increased from a first growth rate toward a second growth rate having a growth rate of 50 μm/h or more; and
a second step of epitaxially growing SiC at a growth rate of 50 μm/h or more.

8. The method for producing a SiC epitaxial wafer according to claim 7,
wherein in the first step, an increase rate of the growth rate is 0.1 μm/(h·sec) to 2.0 μm/(h·sec).
